(19) United States
(12) Patent Application Publication
(10) Pub. No.: US 2024/0304610 A1
(43) Pub. Date: Sep. 12, 2024

(54) DISPLAY DEVICE

(71) Applicant: SAMSUNG DISPLAY CO., LTD., Yongin-si (KR)

(72) Inventors: HYUNGJIN KIM, Yongin-si (KR); HYANGWON MOON, Yongin-si (KR); SIHYUNG AN, Yongin-si (KR); DONGWAN CHOI, Yongin-si (KR)

(21) Appl. No.: 18/398,289

(22) Filed: Dec. 28, 2023

(30) Foreign Application Priority Data
Mar. 7, 2023 (KR) 10-2023-0030126

(51) Int. Cl. H01L 25/16; H01L 25/075; H01L 33/38; H01L 33/62

(52) U.S. Cl. CPC H01L 25/167; H01L 25/0753; H01L 33/382; H01L 33/62

(57) ABSTRACT

A display device includes a substrate including a display area and a pad area spaced apart from the display area. A driving chip is disposed on the substrate. The driving chip overlaps the pad area. A circuit board is disposed on the substrate. The circuit board includes a protrusion part overlapping an end of the pad area and a body part extending from the protrusion part away from the pad area.

### CROSS-REFERENCE TO RELATED APPLICATION(S)

This application claims priority under 35 U.S.C. § 119 to Korean Patent Application No. 10-2023-0030126, filed on Mar. 7, 2023 in the Korean Intellectual Property Office, the disclosure of which is incorporated by reference in its entirety herein.

### 1. TECHNICAL FIELD

Embodiments relate to a display device.

### 2. DISCUSSION OF RELATED ART

A display device is a device that displays an image for providing visual information to a user. An organic light emitting diode display is a display device that has become popular in the electronic industry.

The display device includes a plurality of pixels and a plurality of pads. The plurality of pads may be bonded to a circuit board. The circuit board may apply a signal and/or a voltage to the plurality of pixels. An adhesive, such as an anisotropic conductive film, may be applied to the plurality of pads and pressure may be applied to the plurality of pads and the circuit board to bond the plurality of pads to the circuit board.

### SUMMARY

Embodiments provide a display device with increased display quality.

According to an embodiment of the present disclosure, a display device includes a substrate including a display area and a pad area spaced apart from the display area. A driving chip is disposed on the substrate. The driving chip overlaps the pad area. A circuit board is disposed on the substrate. The circuit board includes a protrusion part overlapping an end of the pad area and a body part extending from the protrusion part away from the pad area.

In an embodiment, the protrusion part may be in direct contact with elements disposed in the pad area. The body part may not be in direct contact with elements disposed in the pad area.

In an embodiment, the substrate may further include a bending area disposed between the display area and the pad area. The bending area may be bendable in a thickness direction of the substrate. The circuit board is disposed under the substrate when the bending area is bent.

In an embodiment, the display device may further include a plurality of first pad electrodes disposed on the substrate. The plurality of first pad electrodes overlaps the pad area and is spaced apart from each other. A plurality of second pad electrodes is disposed on the substrate. The plurality of second pad electrodes overlaps the pad area and is spaced apart from each other. A first anisotropic conductive film is disposed between the plurality of first pad electrodes and the driving chip. The first anisotropic conductive film electrically connects the plurality of first pad electrodes and the driving chip to each other. A second anisotropic conductive film is disposed between the plurality of second pad electrodes and the circuit board. The second anisotropic conductive film electrically connects the plurality of second pad electrodes and the circuit board to each other.

In an embodiment, each of the first anisotropic conductive film and the second anisotropic conductive film may include an epoxy resin.

In an embodiment, the protrusion part of the circuit board may include a plurality of bump electrodes spaced apart from each other.

In an embodiment, the driving chip may be spaced apart from the circuit board in a first direction, and the protrusion part may include a first protrusion part and a second protrusion part spaced apart from the first protrusion part in a second direction intersecting the first direction.

In an embodiment, the circuit board may be a rigid printed circuit board.

According to an embodiment, a display device includes a substrate including a display area and a first pad area spaced apart from the display area. A driving chip is disposed on the substrate. The driving chip overlaps the first pad area. A circuit board is disposed on the substrate. The circuit board overlaps an end of the first pad area. The circuit board includes a second pad area having a plurality of bump electrodes disposed therein. Grooves are defined on both lateral sides of the second pad area.

In an embodiment, the display device may further include a plurality of first pad electrodes disposed on the substrate. The plurality of first pad electrodes overlaps the first pad area and is spaced apart from each other. A plurality of second pad electrodes is disposed on the substrate. The plurality of second pad electrodes overlaps the first pad area and is spaced apart from each other. A first anisotropic conductive film is disposed between the plurality of first pad electrodes and the driving chip. The first anisotropic conductive film electrically connects the plurality of first pad electrodes and the driving chip to each other. A second anisotropic conductive film is disposed between the plurality of second pad electrodes and the circuit board. The second anisotropic conductive film electrically connects the plurality of second pad electrodes and the circuit board to each other.

In an embodiment, wherein each of the first anisotropic conductive film and the second anisotropic conductive film may include an epoxy resin.

In an embodiment, the driving chip may be spaced apart from the circuit board in a first direction. The second pad area may include a first sub-pad area and a second sub-pad area spaced apart from the first sub-pad area in a second direction intersecting the first direction.

In an embodiment, the grooves may include a first groove and a second groove defined at both lateral sides of the first sub-pad area, respectively.

In an embodiment, the grooves may further include a third groove and a fourth groove defined at both lateral sides of the second sub-pad area, respectively.

In an embodiment, the first groove, the second grove, the third groove, and the fourth groove may have a same width in the second direction as each other.

In an embodiment, the first groove, the second groove, the third groove, and the fourth groove may have a same width in the second direction as a width of each of the bump electrodes in the second direction.

According to an embodiment of the present disclosure, a display device includes a substrate including a display area and a pad area spaced apart from the display area. A driving chip is disposed on the substrate. The driving chip overlaps the pad area. A circuit board is disposed under the substrate. The circuit board partially overlaps the pad area. The circuit board is electrically connected to the driving chip through a connection electrode penetrating the substrate.

In an embodiment, the display device may further include a plurality of first pad electrodes disposed on the substrate. The plurality of first pad electrodes overlaps the pad area and is spaced apart from each other. A first anisotropic conductive film is disposed between the plurality of first pad electrodes and the driving chip. The first anisotropic conductive film electrically connects the plurality of first pad electrodes and the driving chip to each other. A second anisotropic conductive film is disposed between the substrate and the circuit board. The connection electrode passes through the second anisotropic conductive film.

In an embodiment, each of the first anisotropic conductive film and the second anisotropic conductive film may include an epoxy resin.

In an embodiment, the circuit board may be a rigid printed circuit board.

A display device according to an embodiment may include a substrate including a display area and a pad area spaced apart from one side of the display area, a driving chip disposed on the substrate and overlapping the pad area, and a circuit board disposed on the substrate and including a protrusion part overlapping an end of the pad area and a body part extending from the protrusion part.

For example, the circuit board may be directly attached to the display panel. Accordingly, an alignment process may be performed only between the display panel and the circuit board. That is, the number of alignment processes may be reduced.

In addition, as the circuit board is directly attached to the display panel, dead space of the display device may be reduced.

In addition, the circuit board according to an embodiment may include a protrusion part, and pad electrodes may be disposed on the protrusion part. Accordingly, damage to conductive balls included in anisotropic conductive film electrically connecting the circuit board and the display panel may be prevented.

### BRIEF DESCRIPTION OF THE DRAWINGS

Illustrative, non-limiting embodiments of the present disclosure will be more clearly understood from the following detailed description in conjunction with the accompanying drawings.

FIG. 1 is a plan view illustrating a display device according to an embodiment of the present disclosure.

FIG. 2 is a plan view illustrating a circuit board included in the display device of FIG. 1 according to an embodiment of the present disclosure.

FIG. 3 is a cross-sectional view of a display device taken along line X-Y of FIG. 1 according to an embodiment of the present disclosure.

FIG. 4 is a cross-sectional view of a display device taken along line I-I′ of FIG. 1 according to an embodiment of the present disclosure.

FIG. 5 is a plan view illustrating a display device according to an embodiment of the present disclosure.

FIG. 6 is a plan view illustrating a circuit board included in the display device of FIG. 5 according to an embodiment of the present disclosure.

FIG. 7 is a plan view illustrating a display device according to an embodiment according to an embodiment of the present disclosure.

FIG. 8 is a cross-sectional view of a display device taken along line X′-Y′ of FIG. 7 according to an embodiment of the present disclosure.

### DETAILED DESCRIPTION OF EMBODIMENTS

Hereinafter, display devices in accordance with embodiments will be described in more detail with reference to the accompanying drawings. The same reference numerals are used for the same components in the drawings, and redundant descriptions of the same components may be omitted for economy of description.

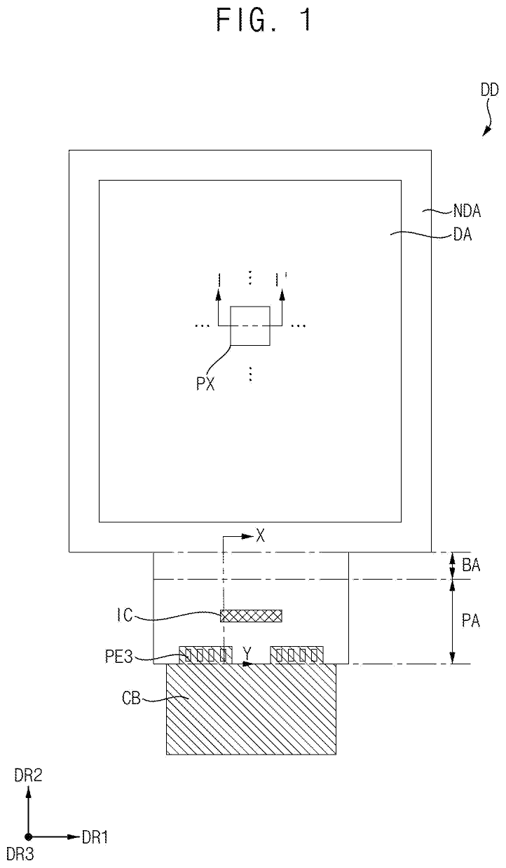

FIG. 1 is a schematic plan view illustrating a display device according to an embodiment.

Referring to FIG. 1, a display device DD may include a display area DA and a non-display area NDA. The display area DA may be defined as an area that emits light to generate an image(s), and the non-display area NDA may be defined as an area in which elements for transmitting a signal to the display area DA are disposed. In an embodiment, the non-display area NDA may not emit light to generate an image.

A plurality of pixels PX may be disposed in the display area DA. The plurality of pixels PX may emit light based on a signal applied from the non-display area NDA. In an embodiment, the plurality of pixels PX may be disposed in the display area DA along a first direction DR1 and a second direction DR2 intersecting the first direction DR1. Accordingly, the display area DA may emit light in an area to display an image.

The non-display area NDA may be located around the display area DA. For example, in an embodiment, the non-display area NDA may completely surround the display area DA (e.g., in the first and second directions DR1, DR2). However, embodiments of the present disclosure are not necessarily limited thereto and the non-display area NDA may not surround at least one side of the display area DA in some embodiments. In an embodiment, the non-display area NDA may include a bending area BA and a pad area PA. The pad area PA may be spaced apart from one side of the display area DA in a direction opposite to the second direction DR2. However, embodiments of the present disclosure are not necessarily limited thereto and the pad area PA may be spaced apart from two or more sides of the display area DA in some embodiments.

The bending area BA may be disposed between the display area DA and the pad area PA in a plan view (e.g., in the second direction DR2). The bending area BA may be bent in a thickness direction of the substrate SUB so that the circuit board CB is disposed under the substrate SUB. For example, the bending area BA may be bent based on a bending axis extending in the first direction DR1. In this embodiment, the display area DA and the pad area PA may overlap each other in a plan view (e.g., overlap in the third direction DR3).

In an embodiment, the non-display area NDA may include a plurality of drivers for driving the plurality of pixels PX. For example, in an embodiment the plurality of drivers may include a gate driver, a light emitting driver, a power voltage generator, a timing controller, or the like. However, embodiments of the present disclosure are not necessarily limited thereto.

A driving chip IC may be disposed on the substrate SUB. In an embodiment, the driving chip IC may at least partially overlap the pad area PA. The driving chip IC may convert a digital data signal of the driving signals into an analog data signal. In addition, the driving chip IC may provide the data signal to the plurality of pixels PX.

A circuit board CB may be disposed on the substrate SUB. In an embodiment, the circuit board CB may partially overlap the pad area PA. For example, as shown in an embodiment of FIG. 1, the circuit board CB may overlap an end of the pad area PA, such as a lower end of the pad area PA in a direction opposite to the second direction DR2. However, embodiments of the present disclosure are not necessarily limited thereto.

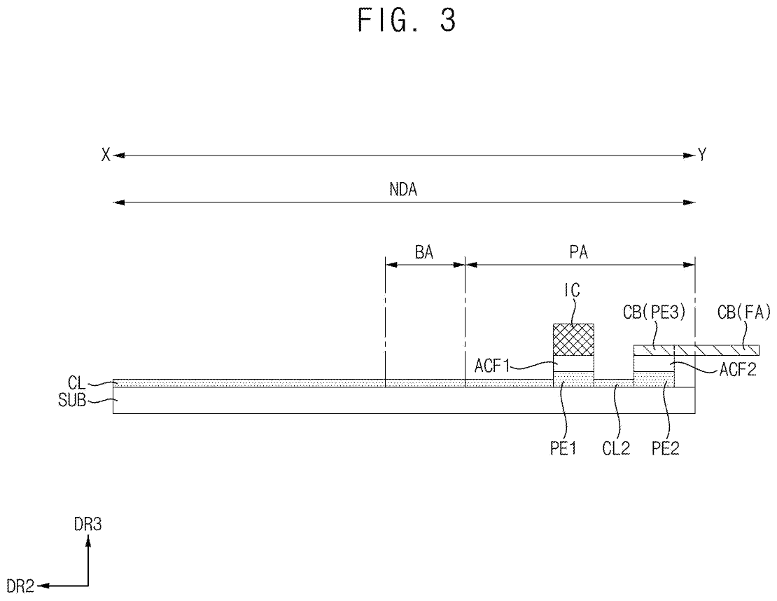

In an embodiment, the circuit board CB may include a plurality of bump electrodes PE3. The plurality of bump electrodes PE3 may be electrically connected to a plurality of second pad electrodes (e.g., a plurality of second pad electrodes PE2 of FIG. 3) disposed on a substrate (e.g., a substrate SUB of FIG. 3). Accordingly, the circuit board CB may apply a driving signal, a driving voltage, or the like to the driving chip IC and the plurality of pixels PX.

The first direction DR1 and the second direction DR2 intersecting the first direction DR1 may be defined. In an embodiment, the first direction DR1 and the second direction DR2 may be perpendicular with each other. However, embodiments of the present disclosure are not necessarily limited thereto. In addition, a third direction DR3 perpendicular to a plane formed by the first direction DR1 and the second direction DR2 may be defined.

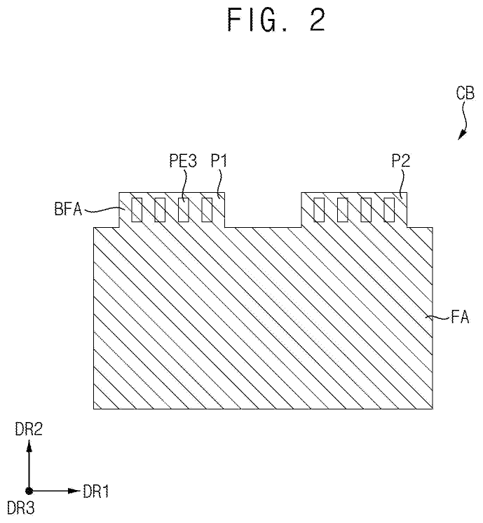

FIG. 2 is a schematic plan view illustrating a circuit board included in the display device of FIG. 1.

Referring to FIGS. 1 and 2, the circuit board CB may include a first protrusion part P1, a second protrusion part P2, and a body part FA. In an embodiment, the body part FA may extend in a plane defined in the first direction DR1 and the second direction DR2 in a direction away from the pad area PA (e.g., in a direction opposite to the second direction DR2). In an embodiment, the body part FA may have a rectangular shape. However, embodiments of the present disclosure are not necessarily limited thereto, and in an embodiment, the body part FA may have a shape different from the rectangular shape (e.g., in a plane defined in the first and second directions DR1, DR2).

The first protrusion part P1 may be a portion extending from the body part FA. For example, in an embodiment the first protrusion part P1 may extend directly from the body part FA (e.g., in the second direction DR2). In an embodiment, the first protrusion part P1 may be a portion extending from a portion of a first surface of the body part FA. In an embodiment, the first protrusion part P1 may have a rectangular shape (e.g., in a plane defined in the first and second directions DR1, DR2). However, embodiments of the present disclosure are not necessarily limited thereto, and in an embodiment, the first protrusion part P1 may have a shape different from the rectangular shape.

In addition, the second protrusion part P2 may be a portion extending from the body part FA. For example, in an embodiment the first protrusion part P1 may extend directly from the body part FA (e.g., in the second direction DR2). In an embodiment, the second protrusion part P2 may be a portion extending from a portion of the first surface of the body part FA. The second protrusion part P2 may be spaced apart from the first protrusion part P1 in the first direction DR1. In an embodiment, the second protrusion part P2 may have a rectangular shape (e.g., in a plane defined in the first and second directions DR1, DR2). However, embodiments of the present disclosure are not necessarily limited thereto, and in an embodiment, the second protrusion part P2 may have a shape different from the rectangular shape (e.g., in a plane defined in the first and second directions DR1, DR2).

In an embodiment, the second protrusion part P2 may have same shape as the first protrusion part P1. However, embodiments of the present disclosure are not necessarily limited thereto, and in an embodiment, the second protrusion part P2 may have a shape different from the first protrusion part P1.

Each of the first protrusion part P1 and the second protrusion part P2 may be in direct contact with elements in the pad area PA and may overlap the pad area PA. For example, each of the first protrusion part P1 and the second protrusion part P2 may be in direct contact with elements in an end portion of the pad area PA and may overlap the pad area PA. The body part FA may not be in direct contact with the pad area PA and may not overlap the pad area PA.

Each of the first protrusion part P1 and the second protrusion part P2 may include a plurality of bump electrodes PE3 disposed thereon. The plurality of bump electrodes PE3 may be electrically connected to the second pad electrodes (e.g., the plurality of second pad electrodes PE2 of FIG. 3) disposed on the substrate (e.g., the substrate SUB of FIG. 3).

In an embodiment, the circuit board CB may be a rigid printed circuit board. However, embodiments of the present disclosure are not necessarily limited to thereto, and in an embodiment, the circuit board CB may be a flexible printed circuit board.

Referring to FIGS. 1, 2, and 3, a transmission line CL may be disposed on the substrate SUB and may extend to the display area DA. The transmission line CL may be connected to a plurality of first pad electrodes PE1. The transmission line CL may transfer signals generated by the circuit board CB and the driving chip IC to the plurality of pixels PX.

The plurality of first pad electrodes PE1 may be disposed on the substrate SUB (e.g., disposed directly thereon in the third direction DR3). The plurality of first pad electrodes PE1 may at least partially overlap the pad area PA. The plurality of first pad electrodes PE1 may be spaced apart from each other in the first direction DR1. The plurality of first pad electrodes PE1 may be connected to the transmission line CL and a connection line CL2.

The connection line CL2 may be disposed on the substrate SUB. The connection line CL2 may connect (e.g., electrically connect) the plurality of first pad electrodes PE1 and a plurality of second pad electrodes PE2 to each other.

A first anisotropic conductive film ACF1 may be disposed on the plurality of first pad electrodes PE1. For example, the first anisotropic conductive film ACF1 may at least partially overlap the pad area PA. The first anisotropic conductive film ACF1 may be disposed between the plurality of first pad electrodes PE1 and the driving chip IC (e.g., in the third direction DR3) to electrically connect the plurality of first pad electrodes PE1 and the driving chip IC to each other.

The plurality of second pad electrodes PE2 may be disposed on the substrate SUB. The plurality of second pad electrodes PE2 may at least partially overlap the pad area PA. The plurality of second pad electrodes PE2 may be spaced apart from each other in the first direction DR1. The plurality of second pad electrodes PE2 may be connected to (e.g., electrically connected to) the connection line CL2. For example, in an embodiment the plurality of second pad electrodes PE2 may be adjacent to the connection line CL2 in a direction opposite to the second direction DR2.

A second anisotropic conductive film ACF2 may be disposed on the plurality of second pad electrodes PE2. For example, the second anisotropic conductive film ACF2 may at least partially overlap the pad area PA. The second anisotropic conductive film ACF2 may be spaced apart from the first anisotropic conductive film ACF1 in a direction opposite to the second direction DR2.

The second anisotropic conductive film ACF2 may be disposed between the plurality of second pad electrodes PE2 and the circuit board CB (e.g., in the third direction DR3) to electrically connect the plurality of second pad electrodes PE2 and the circuit board CB to each other. For example, the second anisotropic conductive film ACF2 may electrically connect the plurality of second pad electrodes PE2 to the plurality of bump electrodes PE3.

The circuit board CB may be disposed on (e.g., disposed directly thereon) the second anisotropic conductive film ACF2. For example, the plurality of bump electrodes PE3 may be disposed on the second anisotropic conductive film ACF2. The circuit board CB may further include a body part FA that does not overlap the second anisotropic conductive film ACF2 in a plan view (e.g., does not overlap in the third direction DR3).

In an embodiment, each of the first anisotropic conductive film ACF1 and the second anisotropic conductive film ACF2 may include an adhesive layer and conductive particles. In an embodiment, each of the conductive particles may include a core including an insulating polymer material and a conductive film surrounding the core and including a conductive metal material.

The adhesive layer may include an insulating polymer material. In an embodiment, the adhesive layer may include an epoxy resin. However, embodiments of the present disclosure are not necessarily limited thereto, and in an embodiment the adhesive layer may include other types of resins such as acrylic resin, phenol resin, melamine resin, diallyl phthalate resin, urea resin, polyimide resin, polystyrene resin, polyurethane resin, polyvinyl acetate, or the like. These materials may be used alone or in combination with each other. The epoxy resin may have a stronger adhesive force than the other types of resins. Therefore, in an embodiment the adhesive layer may include an epoxy resin.

The circuit board CB may be directly attached to elements disposed on the substrate SUB. For example, the circuit board CB may be directly attached to a display panel disposed on the substrate SUB. Accordingly, an alignment process may be performed only between the display panel and the circuit board CB. For example, only one alignment process may be performed.

In addition, as the circuit board CB is directly attached to the display panel, a dead space of the display device DD and thickness of the display device DD may be reduced. The dead space may be an area in which the display device DD does not display an image.

In addition, as mentioned before, in an embodiment the circuit board CB may be a rigid printed circuit board. The rigid printed circuit board may have an elongation different from an elongation of the substrate SUB. Therefore, when the circuit board CB is directly attached to the substrate SUB, the second anisotropic conductive film ACF2 may be damaged by a difference in elongation between the circuit board CB and the substrate SUB. For example, when the circuit board CB is directly attached to the substrate SUB, the conductive particles contained in the second anisotropic conductive film ACF2 may be damaged.

The circuit board CB according to an embodiment may include a first protrusion part P1 and a second protrusion part P2. Each of the first protrusion part P1 and the second protrusion part P2 may include the plurality of bump electrodes PE3 electrically connected to the second anisotropic conductive film ACF2. In addition, each of the first protrusion part P1 and the second protrusion part P2 may include a buffer part BFA disposed on sides of the plurality of bump electrodes PE3.

By disposing only the first protrusion part P1 and the second protrusion part P2 of the circuit board CB on (e.g., directly thereon) the second anisotropic conductive film ACF2, damage to the second anisotropic conductive film ACF2 may be prevented when the circuit board CB is bonded to elements disposed on the substrate SUB. For example, damage to the conductive particles included in the second anisotropic conductive film ACF2 may be prevented.

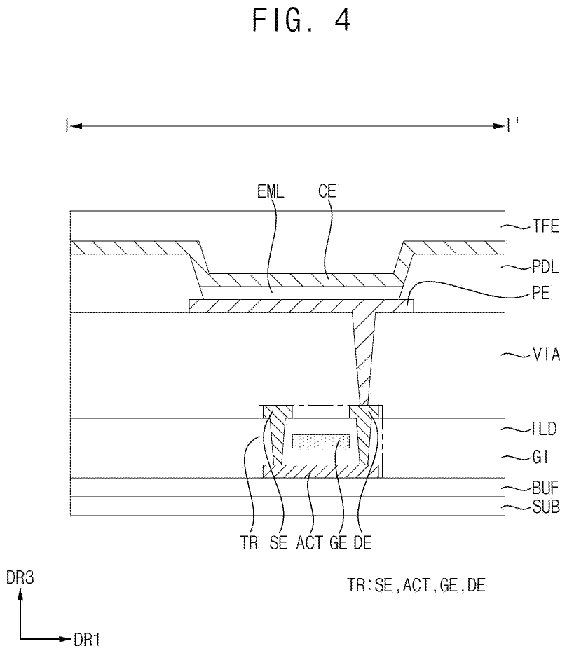

FIG. 4 is a schematic cross-sectional view of the display device of FIG. 1 cut along a line I-I′.

Referring to FIGS. 1 and 4, in an embodiment each of the plurality of pixels PX may include a substrate SUB, a buffer layer BUF, a gate insulating layer GI, an interlayer insulating layer ILD, a via insulating layer VIA, an active layer ACT, a source electrode SE, a gate electrode GE, a drain electrode DE, a pixel electrode PE, a pixel defining layer PDL, a light emitting layer EML, a common electrode CE, and an encapsulating layer TFE.

A substrate SUB may include a transparent material or an opaque material. The substrate SUB may be formed of a transparent resin substrate. Examples of the transparent resin substrate may include a polyimide substrate. However, embodiments of the present disclosure are not necessarily limited thereto. In an embodiment, the polyimide substrate may include a first organic layer, a first barrier layer, a second organic layer, and the like.

Alternatively, the substrate SUB may include a quartz substrate, a synthetic quartz substrate, a calcium fluoride substrate, a fluorine-doped quartz substrate, a sodalime substrate, a non-alkali glass substrate, and the like. These materials may be used alone or in combination with each other.

A buffer layer BUF may be disposed on the substrate SUB (e.g., disposed directly thereon in the third direction DR3). The buffer layer BUF may prevent metal atoms or impurities from diffusing from the substrate SUB to a transistor TR. In addition, the buffer layer BUF can increase the flatness of a surface of the substrate SUB when the surface of the substrate SUB is not uniform.

For example, in an embodiment the buffer layer BUF may include an inorganic material such as silicon oxide, silicon nitride, silicon oxynitride, and the like. These materials may be used alone or in combination with each other. However, embodiments of the present disclosure are not necessarily limited thereto and the buffer layer BUF may be composed of various other materials.

An active layer ACT may be disposed on the buffer layer BUF (e.g., disposed directly thereon in the third direction DR3). In an embodiment, the active layer ACT may include a metal oxide semiconductor, an inorganic semiconductor (e.g., amorphous silicon, polysilicon), an organic semiconductor, and the like. These materials may be used alone or in combination with each other. The active layer ACT may include a source area, a drain area, and a channel area disposed between the source area and the drain area.

In an embodiment, the metal oxide semiconductor may include a binary compound (“ABₓ”), a ternary compound (“ABₓC_{y}”), a tetragonal compound (“ABₓC_{y}D_{z}”), and the like including indium (“In”), zinc (“Zn”), gallium (“Ga”), tin (“Sn”), titanium (“Ti”), aluminum (“Al”), hafnium (“Hf”), zirconium (“Zr”), magnesium (“Mg”), and the like. However, embodiments of the present disclosure are not necessarily limited thereto.

For example, the metal oxide semiconductor may include zinc oxide (“ZnOₓ”), gallium oxide (“GaOₓ”), tin oxide (“SnOₓ”), indium oxide (“InOₓ”), indium gallium oxide (“IGO”), indium zinc oxide (“IZO”), indium tin oxide (“ITO”), indium zinc tin oxide (“IZTO”), and indium gallium zinc oxide (“IGZO”). These materials may be used alone or in combination with each other.

A gate insulating layer GI may be disposed on the buffer layer BUF (e.g., disposed directly thereon in the third direction DR3). The gate insulating layer GI may sufficiently cover the active layer ACT, and may have a substantially flat upper surface without generating a step around the active layer ACT. Alternatively, the gate insulating layer GI may cover the active layer ACT and may be disposed along a profile of the active layer ACT.

For example, in an embodiment the gate insulating layer GI may include inorganic materials such as silicon oxide (“SiOₓ”), silicon nitride (“SiNₓ”), silicon carbide (“SiCₓ”), silicon oxynitride (“SiOₓN_{y}”), silicon oxycarbide (“SiOₓC_{y}”), and the like. These materials may be used alone or in combination with each other. However, embodiments of the present disclosure are not necessarily limited thereto and the gate insulating layer GI may be composed of various other materials.

A gate electrode GE may be disposed on the gate insulating layer GI (e.g., disposed directly thereon in the third direction DR3). The gate electrode GE may overlap the channel area of the active layer ACT (e.g., in the third direction DR3).

In an embodiment, the gate electrode GE may include a metal, an alloy metal nitride, a conductive metal oxide, a transparent conductive material, or the like. Examples of the metal may include silver (“Ag”), molybdenum (“Mo”), aluminum (“Al”), tungsten (“W”), copper (“Cu”), nickel (“Ni”), chromium (“Cr”), titanium (“Ti”), tantalum (“Ta”), platinum (“Pt”), scandium (“Sc”), or the like. Examples of the conductive metal oxide may include indium tin oxide, indium zinc oxide, or the like. In addition, examples of the metal nitride may include aluminum nitride (“AlNₓ”), tungsten nitride (“WNₓ”), chromium nitride (“CrNₓ”), or the like. Each of these materials may be used alone or in combination with each other. However, embodiments of the present disclosure are not necessarily limited thereto and the gate electrode GE may be composed of various other materials.

An interlayer insulating layer ILD may be disposed on the gate insulating layer GI (e.g., disposed directly thereon in the third direction DR3). The interlayer insulating layer ILD may sufficiently cover the gate electrode GE, and may have a substantially flat upper surface without generating a step around the gate electrode GE. Alternatively, the interlayer insulating layer ILD may cover the gate electrode GE, and may be disposed along a profile of the gate electrode GE.

For example, in an embodiment the interlayer insulating layer ILD may include inorganic materials such as silicon oxide, silicon nitride, silicon carbide, silicon oxynitride, silicon oxycarbide, or the like. These materials may be used alone or in combination with each other. However, embodiments of the present disclosure are not necessarily limited thereto and the interlayer insulating layer ILD may be composed of various other materials.

A source electrode SE may be disposed on the interlayer insulating layer ILD (e.g., disposed directly thereon). The source electrode SE may be connected to the source area of the active layer ACT through a contact hole penetrating the gate insulating layer GI and the interlayer insulating layer ILD.

A drain electrode DE may be disposed on the interlayer insulating layer ILD (e.g., disposed directly thereon). The drain electrode DE may be connected to the drain area of the active layer ACT through a contact hole penetrating the gate insulating layer GI and the interlayer insulating layer ILD.

For example, in an embodiment the source electrode SE may include a metal, an alloy, a metal nitride, a conductive metal oxide, a transparent conductive material, and the like. These materials may be used alone or in combination with each other. In an embodiment, the drain electrode DE may be formed through the same process as the source electrode SE and may include the same material as the source electrode SE.

The transistor TR may include the active layer ACT, the source electrode SE, the gate electrode GE, and the drain electrode DE.

A via insulating layer VIA may be disposed on the interlayer insulating layer ILD (e.g., disposed directly thereon in the third direction DR3). The via insulating layer VIA may sufficiently cover the source electrode SE and the drain electrode DE. The via insulating layer VIA may include an organic material. For example, in an embodiment the via insulating layer VIA may include organic materials such as phenolic resin, acrylic resin, polyimide resin, polyamide resin, siloxane resin, epoxy resin, and the like. These materials may be used alone or in combination with each other. However, embodiments of the present disclosure are not necessarily limited thereto and the via insulating layer VIA may be composed of various other materials.

A pixel electrode PE may be disposed on the via insulating layer VIA (e.g., disposed directly thereon in the third direction DR3). The pixel electrode PE may be connected to the drain electrode DE through a contact hole penetrating the via insulating layer VIA.

In an embodiment, the pixel electrode PE may include a metal, an alloy, a metal nitride, a conductive metal oxide, a transparent conductive material, and the like. These materials be used alone or in combination with each other. However, embodiments of the present disclosure are not necessarily limited thereto and the pixel electrode PE may include various other materials. In an embodiment, the pixel electrode PE may have a stacked structure including ITO/Ag/ITO. For example, the pixel electrode PE may operate as an anode.

A pixel defining layer PDL may be disposed on the via insulating layer VIA (e.g., disposed directly thereon in the third direction DR3). The pixel defining layer PDL may cover both side portions of the pixel electrode PE. In addition, an opening exposing a portion of the upper surface of the pixel electrode PE may be defined in the pixel defining layer PDL. For example, in an embodiment the opening may expose a center portion of the upper surface of the pixel electrode PE. However, embodiments of the present disclosure are not necessarily limited thereto.

For example, in an embodiment the pixel defining layer PDL may include an inorganic material or an organic material. In an embodiment, the pixel defining layer PDL may include an organic material such as an epoxy resin, a siloxane resin, and the like. These materials may be used alone or in combination with each other. However, embodiments of the present disclosure are not necessarily limited thereto and the material of the pixel defining layer PDL may vary. In an embodiment, the pixel defining layer PDL may further include a light blocking material containing a black pigment, a black dye, and the like.

A light emitting layer EML may be disposed on the pixel electrode PE. The light emitting layer EML may include an organic material that emits light of a predetermined color. For example, the light emitting layer EML may include an organic material that emits red light. However, embodiments of the present disclosure are not necessarily limited thereto, and the light emitting layer EML may emit light of a different color from red light.

A common electrode CE may be disposed on the light emitting layer EML and the pixel defining layer PDL. In an embodiment, the common electrode CE may include a metal, an alloy, a metal nitride, a conductive metal oxide, a transparent conductive material, or the like. These materials may be used alone or in combination with each other. However, embodiments of the present disclosure are not necessarily limited thereto and the common electrode CE may include various other materials. The common electrode CE may operate as a cathode.

An encapsulation layer TFE may be disposed on (e.g., disposed directly thereon in the third direction DR3) the common electrode CE. The encapsulation layer TFE may prevent impurities and moisture from penetrating into the pixel electrode PE, the light emitting layer EML, and the common electrode CE from the outside. The encapsulation layer TFE may include at least one inorganic layer and at least one organic layer.

For example, in an embodiment the inorganic layer may include silicon oxide, silicon nitride, silicon oxynitride, and the like. These materials may be used alone or in combination with each other. The organic layer may include a polymer cured product such as polyacrylate. However, embodiments of the present disclosure are not necessarily limited thereto and the inorganic layer and organic layer may include various other materials.

Although an embodiment of each of the plurality of pixels PX has been described with reference to FIG. 4, each of the plurality of pixels PX is not necessarily limited to the structure shown in FIG. 4. For example, each of the plurality of pixels PX may include all structures that receive an electrical signal and emit light having a luminance corresponding to the intensity of the electrical signal.

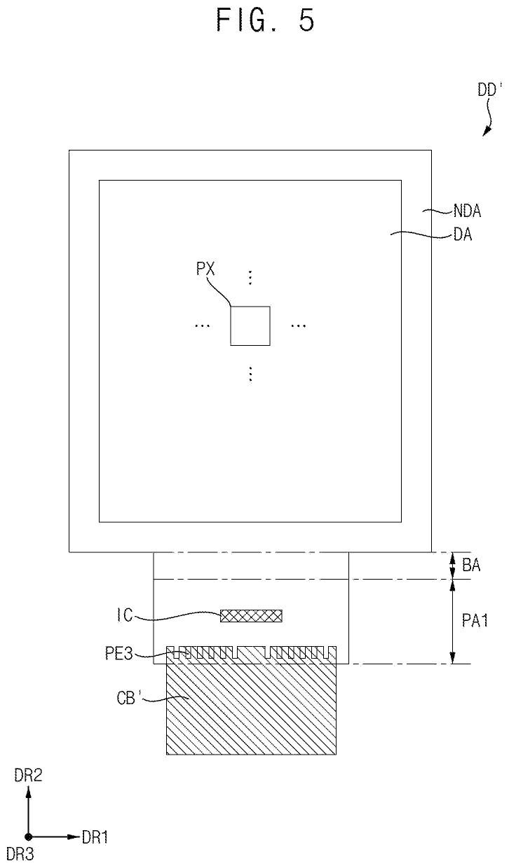

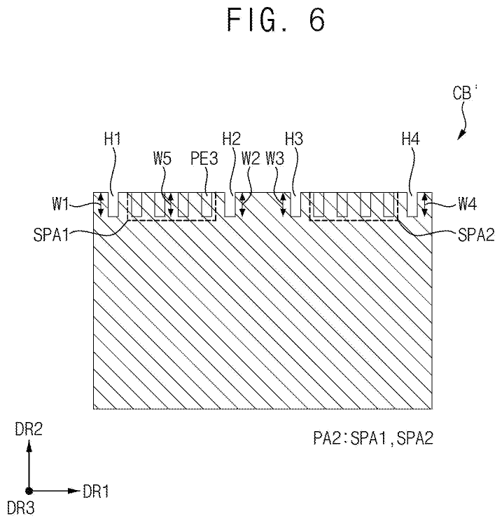

FIG. 5 is a schematic plan view illustrating a display device according to another embodiment. FIG. 6 is a schematic plan view illustrating a circuit board included in the display device of FIG. 5.

In describing a display device DD′ according to an embodiment of FIG. 5, substantially the same reference numerals as the display device DD of FIG. 1 may be assigned, and a detailed description thereof may be omitted for economy of description.

Referring to FIGS. 5 and 6, a display device DD′ according to an embodiment may include a display area DA and a non-display area NDA. The non-display area NDA may be located around the display area DA (e.g., in the first and second directions DR1, DR2). In an embodiment, the non-display area NDA may include a bending area BA and a first pad area PA1. For example, the first pad area PA1 may be spaced apart from one side of the display area DA in a direction opposite to the second direction DR2.

The bending area BA may be disposed between the display area DA and the first pad area PA1 in a plan view (e.g., in the second direction DR2). The bending area BA may be bent in a thickness direction of the substrate SUB so that the circuit board CB is disposed below the substrate SUB. For example, the bending area BA may be bent based on a bending axis extending in the first direction DR1. In this embodiment, the display area DA and the first pad area PA1 may overlap each other in a plan view (e.g., may overlap each other in the third direction DR3).

A driving chip IC may be disposed on the substrate SUB. The driving chip IC may at least partially overlap the first pad area PA1. The driving chip IC may convert a digital data signal of driving signals into an analog data signal. In addition, the driving chip IC may provide the data signal to a plurality of pixels PX.

A circuit board CB may be disposed on the substrate SUB. The circuit board CB′ may partially overlap the first pad area PA1. For example, in an embodiment the circuit board CB′ may overlap an end portion of the first pad area PA1, such an end portion of the first pad area PA1 in the direction opposite to the second direction DR2.

The circuit board CB′ may include a plurality of bump electrodes PE3. The plurality of bump electrodes PE3 may be electrically connected to the plurality of second pad electrodes (e.g., the plurality of second pad electrodes PE2 of FIG. 3) disposed on the substrate (e.g., the substrate SUB of FIG. 3). Accordingly, the circuit board CB′ may apply a driving signal, a driving voltage, or the like to the driving chip IC and the plurality of pixels PX.

In an embodiment, the circuit board CB′ may include a second pad area PA2. The second pad area PA2 may include a first sub-pad area SPA1 and a second sub-pad area SPA2. The second sub-pad area SPA2 may be spaced apart from the first sub-pad area SPA1 in the first direction DR1. The plurality of bump electrodes PE3 may be disposed in each of the first sub-pad area SPA1 and the second sub-pad area SPA2.

In an embodiment, a first groove H1 and a second groove H2 may be defined at both side portions (e.g., lateral side portions in the first direction DR1) of the first sub-pad area SPA1, respectively. For example, the first groove H1 may be spaced apart from the first sub-pad area SPA1 in a direction opposite to the first direction DR1. In addition, the second groove H2 may be spaced apart from the first sub-pad area SPA1 in the first direction DR1.

In addition, a third groove H3 and a fourth groove H4 may be defined at both side portions (e.g., lateral side portions in the first direction DR1) of the second sub-pad area SPA2, respectively. For example, the third groove H3 may be spaced apart from the second sub-pad area SPA2 in a direction opposite to the first direction DR1. In addition, the fourth groove H4 may be spaced apart from the second sub-pad area SPA2 in the first direction DR1.

In an embodiment, a width W1 (e.g., length in the second direction DR2) of the first groove H1, a width W2 (e.g., length in the second direction DR2) of the second grove H2, a width W3 (e.g., length in the second direction DR2) of the third groove H3, and a width W4 (e.g., length in the second direction DR2) of the fourth groove H4 may be the same to each other. However, embodiments of the present disclosure are not necessarily limited thereto. For example, in an embodiment, a width W1 of the first groove H1, a width W2 of the second grove H2, a width W3 of the third groove H3, and a width W4 of the fourth groove H4 each in the second direction DR2 may be different from each other. In an embodiment, only some of the first groove H1, the second groove H2, the third groove H3, and the fourth groove H4 may have the same width as each other. For example, in an embodiment the width W1 of the first groove H1 and the width W2 of the second groove H2 may be the same as each other, and the width W2 of the second groove H2 and the width W3 of the third groove H3 may be different from each other.

In an embodiment, each of the width W1 of the first groove H1, the width W2 of the second groove H2, the width W3 of the third groove H3, and the width W4 of the fourth groove H4 in the second direction DR2 may be the same as a width W5 (e.g., length in the second direction DR2) of each of the bump electrodes PE3 in the second direction DR2. However, embodiments of the present disclosure are not necessarily limited thereto. For example, in an embodiment, each of the width W1 of the first groove H1, the width W2 of the second groove H2, the width W3 of the third groove H3, and the width W4 of the fourth groove H4 in the second direction DR2 may be different from the width W5 of each of the bump electrodes PE3 in the second direction DR2

In an embodiment, the circuit board CB′ may be a rigid printed circuit board. The rigid printed circuit board may have an elongation that is different from an elongation of the substrate (e.g., the substrate SUB of FIG. 3). Therefore, in an embodiment in which the circuit board CB′ is directly attached to the substrate, the second anisotropic conductive film (e.g., the second anisotropic conductive film ACF2 of FIG. 3) may be damaged by the difference in elongation between the circuit board CB′ and the substrate. For example, when the circuit board CB is directly attached to the substrate, the conductive particles contained in the second anisotropic conductive film may be damaged.

The circuit board CB′ according to an embodiment may define the first groove H1, the second groove H2, the third groove H3, and the fourth groove H4. Accordingly, when the circuit board CB is bonded to the substrate, damage to the second anisotropic conductive film may be prevented. For example, damage to the conductive particles included in the second anisotropic conductive film may be prevented.

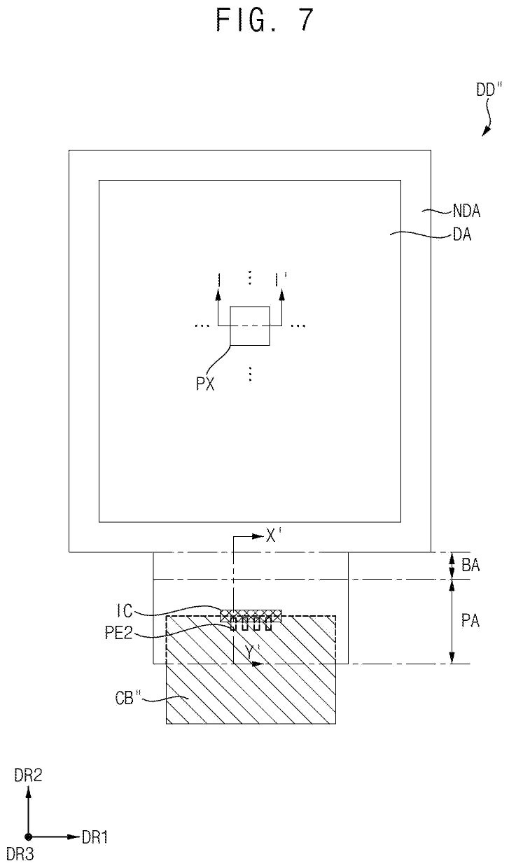

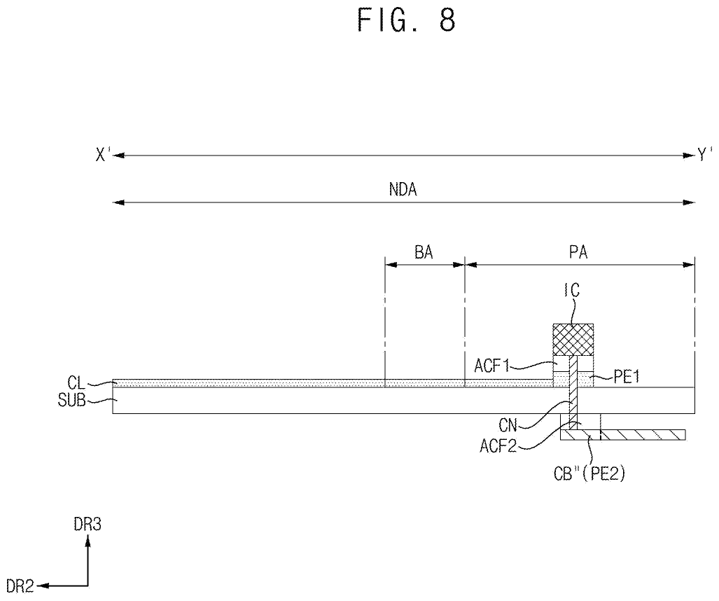

FIG. 7 is a schematic plan view illustrating a display device according to an embodiment. FIG. 8 is a schematic cross-sectional view of the display device of FIG. 7 cut along an X′-Y′ line.

In describing a display device DD″ according to an embodiment of FIG. 7, substantially the same reference numerals as the display device DD of FIG. 1 may be assigned, and a detailed description thereof may be omitted for economy of description.

Referring to FIGS. 7 and 8, a driving chip IC may be disposed on the substrate SUB. The driving chip IC may at least partially overlap the pad area PA. The driving chip IC may convert a digital data signal of the driving signals into an analog data signal. In addition, the driving chip IC may provide the data signal to a plurality of pixels PX.

A circuit board CB″ may be disposed under the substrate SUB. The circuit board CB″ may partially overlap the pad area PA. For example, the circuit board CB″ may include a portion overlapping the pad area PA and a portion not overlapping the pad area PA. The circuit board CB″ may include a plurality of bump electrodes PE2.

A transmission line CL may be disposed on the substrate SUB. The transmission line CL may be connected to a plurality of first pad electrodes PE1. The transmission line CL may transfer signals generated by the circuit board CB″ and the driving chip IC to the plurality of pixels PX.

The plurality of first pad electrodes PE1 may be disposed on the substrate SUB. The plurality of first pad electrodes PE1 may at least partially overlap the pad area PA. The plurality of first pad electrodes PE1 may be spaced apart from each other in a first direction DR1. The plurality of first pad electrodes PE1 may be connected to the transmission line CL. The transmission line CL may be connected to a driver mounted on the driving chip IC through the plurality of first pad electrodes PE1.

A first anisotropic conductive film ACF1 may be disposed on the plurality of first pad electrodes PE1. The first anisotropic conductive film ACF1 may at least partially overlap the pad area PA. The first anisotropic conductive film ACF1 may be disposed between the plurality of first pad electrodes PE1 and the driving chip IC (e.g., in the third direction DR3) to electrically connect the plurality of first pad electrodes PE1 and the driving chip IC to each other.

A second anisotropic conductive film ACF2 may be disposed under the substrate SUB (e.g., in the direction opposite to the third direction DR3). The second anisotropic conductive film ACF2 may at least partially overlap the pad area PA. For example, the second anisotropic conductive film ACF2 may partially overlap the first anisotropic conductive film ACF1 in a plan view.

The circuit board CB″ may be disposed under the second anisotropic conductive film ACF2. For example, the plurality of bump electrodes PE2 may be disposed under the second anisotropic conductive film ACF2 (e.g., in the direction opposite to the third direction DR3). The circuit board CB″ may further include a portion that does not overlap the second anisotropic conductive film ACF2.

A connection electrode CN may connect the driving chip IC and the circuit board CB″. The connection electrode CN may penetrate (e.g., pass through) the first anisotropic conductive film ACF1, the plurality of first pad electrodes PE1, the substrate SUB, and the second anisotropic conductive film ACF2. Through the connection electrode CN, the circuit board CB″ may transmit a driving signal, a driving voltage, or the like to the driving chip IC and the plurality of pixels PX.

Embodiments of the present disclosure can be applied to various display devices. For example, the present disclosure is applicable to various display devices such as display devices for vehicles, ships and aircraft, portable communication devices, display devices for exhibition or information transmission, medical display devices, and the like. However, embodiments of the present disclosure are not necessarily limited thereto.

The foregoing is illustrative of embodiments and is not to be construed as limiting thereof. Although a few non-limiting embodiments have been described, those skilled in the art will readily appreciate that many modifications are possible without materially departing from the present disclosure. Accordingly, all such modifications are intended to be included within the scope of the present disclosure. Therefore, it is to be understood that the foregoing is illustrative of various embodiments and is not to be construed as limited to the specific described embodiments, and that modifications to the described embodiments, as well as other embodiments, are intended to be included within the scope of the present disclosure.

What is claimed is:

1. A display device comprising:
a substrate including a display area and a pad area spaced apart from the display area;
a driving chip disposed on the substrate, the driving chip overlapping the pad area; and
a circuit board disposed on the substrate, the circuit board including a protrusion part overlapping an end of the pad area and a body part extending from the protrusion part away from the pad area.

2. The display device of claim 1, wherein the protrusion part is in direct contact with elements disposed in the pad area, and the body part is not in direct contact with elements disposed in the pad area.

3. The display device of claim 1, wherein:
the substrate further includes a bending area disposed between the display area and the pad area; and
the bending area is bendable in a thickness direction of the substrate, wherein the circuit board is disposed under the substrate when the bending area is bent.

4. The display device of claim 1, further comprising:
a plurality of first pad electrodes disposed on the substrate, the plurality of first pad electrodes overlaps the pad area and is spaced apart from each other;
a plurality of second pad electrodes disposed on the substrate, the plurality of second pad electrodes overlaps the pad area and is spaced apart from each other;
a first anisotropic conductive film disposed between the plurality of first pad electrodes and the driving chip, the first anisotropic conductive film electrically connecting the plurality of first pad electrodes and the driving chip to each other; and
a second anisotropic conductive film disposed between the plurality of second pad electrodes and the circuit board, the second anisotropic conductive film electrically connecting the plurality of second pad electrodes and the circuit board to each other.

5. The display device of claim 4, wherein each of the first anisotropic conductive film and the second anisotropic conductive film includes an epoxy resin.

6. The display device of claim 1, wherein the protrusion part of the circuit board includes a plurality of bump electrodes spaced apart from each other.

7. The display device of claim 1, wherein:
the driving chip is spaced apart from the circuit board in a first direction; and
the protrusion part includes a first protrusion part and a second protrusion part spaced apart from the first protrusion part in a second direction intersecting the first direction.

8. The display device of claim 1, wherein the circuit board is a rigid printed circuit board.

9. A display device comprising:
a substrate including a display area and a first pad area spaced apart from the display area;
a driving chip disposed on the substrate, the driving chip overlapping the first pad area; and
a circuit board disposed on the substrate, the circuit board overlapping an end of the first pad area, the circuit board including a second pad area having a plurality of bump electrodes disposed therein, wherein grooves are defined on both lateral sides of the second pad area.

10. The display device of claim 9, further comprising:
a plurality of first pad electrodes disposed on the substrate, the plurality of first pad electrodes overlaps the first pad area and is spaced apart from each other;
a plurality of second pad electrodes disposed on the substrate, the plurality of second pad electrodes overlaps the first pad area and is spaced apart from each other;
a first anisotropic conductive film disposed between the plurality of first pad electrodes and the driving chip, the first anisotropic conductive film electrically connecting the plurality of first pad electrodes and the driving chip to each other; and
a second anisotropic conductive film disposed between the plurality of second pad electrodes and the circuit board, the second anisotropic conductive film electrically connecting the plurality of second pad electrodes and the circuit board to each other.

11. The display device of claim 10, wherein each of the first anisotropic conductive film and the second anisotropic conductive film includes an epoxy resin.

12. The display device of claim 9, wherein:
the driving chip is spaced apart from the circuit board in a first direction; and
the second pad area includes a first sub-pad area and a second sub-pad area spaced apart from the first sub-pad area in a second direction intersecting the first direction.

13. The display device of claim 12, wherein the grooves include a first groove and a second groove defined at both lateral sides of the first sub-pad area, respectively.

14. The display device of claim 13, wherein the grooves further include a third groove and a fourth groove defined at both lateral sides of the second sub-pad area, respectively.

15. The display device of claim 14, wherein the first groove, the second groove, the third groove, and the fourth groove have a same width in the second direction as each other.

16. The display device of claim 14, wherein the first groove, the second groove, the third groove, and the fourth groove have a same width in the second direction as a width of each of the plurality of bump electrodes in the second direction.

17. A display device comprising:
a substrate including a display area and a pad area spaced apart from the display area;
a driving chip disposed on the substrate, the driving chip overlapping the pad area; and
a circuit board disposed under the substrate, the circuit board partially overlapping the pad area, wherein the circuit board is electrically connected to the driving chip through a connection electrode penetrating the substrate.

18. The display device of claim 17, further comprising:
a plurality of first pad electrodes disposed on the substrate, the plurality of first pad electrodes overlaps the pad area and is spaced apart from each other;
a first anisotropic conductive film disposed between the plurality of first pad electrodes and the driving chip, the first anisotropic conductive film electrically connecting the plurality of first pad electrodes and the driving chip to each other; and
a second anisotropic conductive film disposed between the substrate and the circuit board, the connection electrode passes through the second anisotropic conductive film.

19. The display device of claim 18, wherein each of the first anisotropic conductive film and the second anisotropic conductive film includes an epoxy resin.

20. The display device of claim 17, wherein the circuit board is a rigid printed circuit board.
